(19) United States
(12) Patent Application Publication
(10) Pub. No.: US 2026/0089976 A1
(43) Pub. Date: Mar. 26, 2026

(54) MEMORY DEVICE AND OPERATING METHOD OF MEMORY DEVICE

(71) Applicant: SK hynix Inc., Icheon-si (KR)

(72) Inventors: Gap Sok DO, Icheon-si (KR); Jang Gun KIM, Icheon-si (KR); Ung Hee PARK, Icheon-si (KR); Yoon Cheol BAE, Icheon-si (KR); In Seon YEO, Icheon-si (KR)

(21) Appl. No.: 19/187,740

(22) Filed: Apr. 23, 2025

(30) Foreign Application Priority Data
Sep. 26, 2024 (KR) 10-2024-0130629

(51) Int. Cl. H10B 63/00; G11C 13/00

(52) U.S. Cl. CPC H10B 63/24; G11C 13/00

(57) ABSTRACT

A memory device may include a plurality of vertical bit lines disposed between a plurality of first access lines and a plurality of second access lines, a plurality of first selection circuits between the plurality of vertical bit lines and the plurality of first access lines, and a plurality of second selection circuits between the plurality of vertical bit lines and the plurality of second access lines.

### CROSS-REFERENCE TO RELATED APPLICATION

This application claims priority under 35 U.S.C. § 119(a) to Korean Patent Application No. 10-2024-0130629, filed in the Korean Intellectual Property Office on Sep. 26, 2024, the entire contents of which are incorporated herein by reference.

### BACKGROUND

### 1. Technical Field

Embodiments relate to an integrated circuit technique and, particularly, to a memory device and an operating method of a memory device.

### 2. Related Art

Recently, as an electronic device is reduced in size, has lower power consumption and higher performance, and is diversified, memory capable of storing information is required for various electronic devices, such as computers and portable communication devices. Furthermore, memory having various characteristics are the subject of ongoing research.

Memory that is being researched includes memory capable of storing data by using a characteristic in which the memory switches between different resistance states depending on a voltage or current applied thereto. Such memory includes resistive random access memory (RRAM), phase change random access memory (PRAM), ferroelectric random access memory (FRAM), magnetic random access memory (MRAM), and an E-fuse.

### SUMMARY

In an embodiment, a memory device may include a plurality of vertical bit lines that is disposed between a plurality of first access lines and a plurality of second access lines, a plurality of first selection circuits that is formed between the plurality of vertical bit lines and a plurality of first access lines, and a plurality of second selection circuits that is formed between the plurality of vertical bit lines and the plurality of second access lines.

In an embodiment, a memory device may include a plurality of first selection circuits that is formed on a plurality of first access lines, a plurality of vertical bit lines that is formed on the plurality of first selection circuits, respectively, a memory material that surrounds the side of each of the plurality of vertical bit lines, a plurality of second selection circuits that is formed on the plurality of vertical bit lines, and a plurality of second access lines formed on the plurality of second selection circuits. Each of the plurality of first selection circuits and the plurality of second selection circuits may be set so that a current flows in a first direction or a second direction.

In an embodiment, an operating method of a memory device may include receiving a command, selecting one vertical bit line, among a plurality of vertical bit lines, in the state in which a plurality of word planes has been floated, performing an operation according to the command on at least one memory cell, among a plurality of memory cells formed in the selected one vertical bit line, and initializing the selected one vertical bit line.

### BRIEF DESCRIPTION OF THE DRAWINGS

FIG. 1 illustrates a memory cell array according to an embodiment of the present disclosure.

FIGS. 2 and 3 illustrate write operations of a memory cell array according to embodiments of the present disclosure.

FIGS. 4 to 6 illustrate a memory cell array including a selection circuit according to embodiments of the present disclosure.

FIGS. 7 and 8 illustrate operations of a selection circuit according to embodiments of the present disclosure.

FIGS. 9 to 11 illustrate operations of selecting a vertical bit line of the memory cell array according to embodiments of the present disclosure.

FIGS. 12 and 13 illustrate write operations of a memory cell array according to embodiments of the present disclosure.

FIG. 14 is a flowchart that illustrates an operation of a memory device including a memory cell array according to an embodiment of the present disclosure.

FIG. 15 illustrates an operation of a memory device including a memory cell array according to another embodiment of the present disclosure.

FIG. 16 is a flowchart that illustrates an operation of a memory device including a memory cell array according to another embodiment of the present disclosure.

### DETAILED DESCRIPTION

Hereinafter, embodiments according to the technical spirit of the present disclosure are described with reference to the accompanying drawings.

Embodiments of the present disclosure provide a memory device including a three-dimensional (3-D) memory cell array and a method of operating the memory device.

Embodiments may reduce manufacturing complexity, which may reduce manufacturing costs and improve yields for a memory cell array.

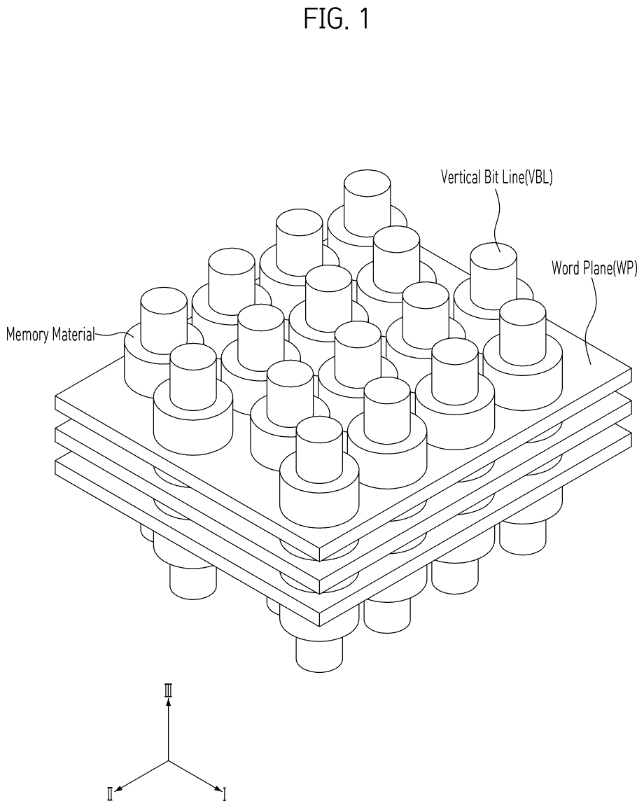

FIG. 1 is a diagram that illustrates a memory cell array according to an embodiment of the present disclosure.

Referring to FIG. 1, a memory cell array according to an embodiment of the present disclosure may include a cell, a vertical bit line VBL, and a word plane WP.

The word plane WP may be formed to extend in a first direction I and a second direction II. Furthermore, if the memory cell array includes a plurality of word planes WP, the memory cell array may be configured so that the plurality of word planes WP formed to extend in the first direction I and the second direction II are stacked in a third direction III. The word planes WP may include a conductive material. Embodiments comprise at least one word plane WP that extends in the first direction I and the second direction II on a plane that is defined in the first direction I and the second direction II. While FIG. 1 illustrates an embodiment with three word planes WP, the present disclosure does not limit the number of word planes WP that may be present in a memory cell array. For example, a memory cell array according to another embodiment may include a plurality of word planes that are formed on the same plane that is defined in the first direction I and the second direction II. Furthermore, a plurality of word planes that are planar in the first direction I and the second direction II may be stacked in the third direction III and included in the memory cell array.

The vertical bit line VBL in FIG. 1 may be formed to extend in the third direction III. The memory cell array may include a plurality of vertical bit lines VBL that extend in the third direction III. The vertical bit lines VBL may penetrate the word plane WP in the third direction III. The vertical bit line VBL may include a conductive material. While the vertical bit line VBL in FIG. 1 is illustrated as having a circular column shape in an embodiment, the cross-sectional shape of the vertical bit line VBL is not particularly limited. For example, in other embodiments, the vertical bit line VBL may have a polygonal or elliptical cross-sectional shape.

A memory element comprising a memory material may surround or wrap around the longitudinal axis of vertical bit line VBL, e.g. the third direction III in FIG. 1. Put another way, the memory material may wrap around or surround at least a side, for example all sides, of the vertical bit line VBL. If the vertical bit line VBL has a circular cross-sectional shape, the memory material may cover the entire circumference of the circular shape, and if the vertical bit line VBL has a square cross-sectional shape, the memory material may cover up to all four sides of the square shape. The memory material may include a chalcogenide-based material. The level of a threshold voltage of the memory material may be changed depending on the direction of a current that passes through the memory material. In this case, the memory cell may comprise the memory material between the word plane WP and the vertical bit line VBL. The level of the threshold voltage of the memory cell may be changed depending on the direction of a current between the word plane WP and the vertical bit line VBL.

Accordingly, a memory cell array according to an embodiment of the present disclosure may include a plurality of word planes WP that are stacked in the third direction III and that extend in the first direction I and the second direction II, a plurality of vertical bit lines VBL that extend in the third direction III and that penetrate the plurality of word planes WP, and a memory material that surrounds each of the plurality of vertical bit lines VBL. Accordingly, a memory cell array according to an embodiment of the present disclosure may include a plurality of memory cells that are each formed between the word plane WP and each of the vertical bit lines VBL.

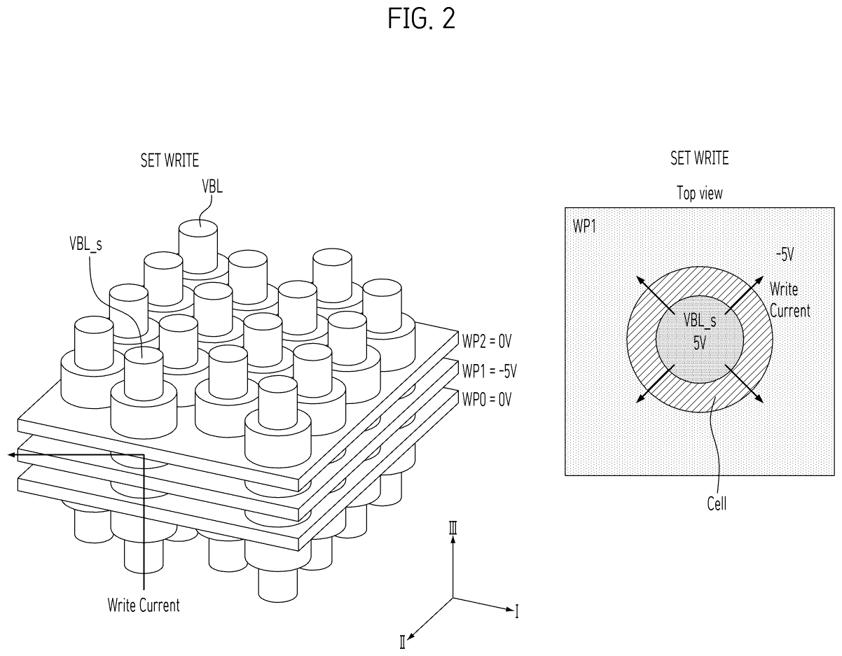

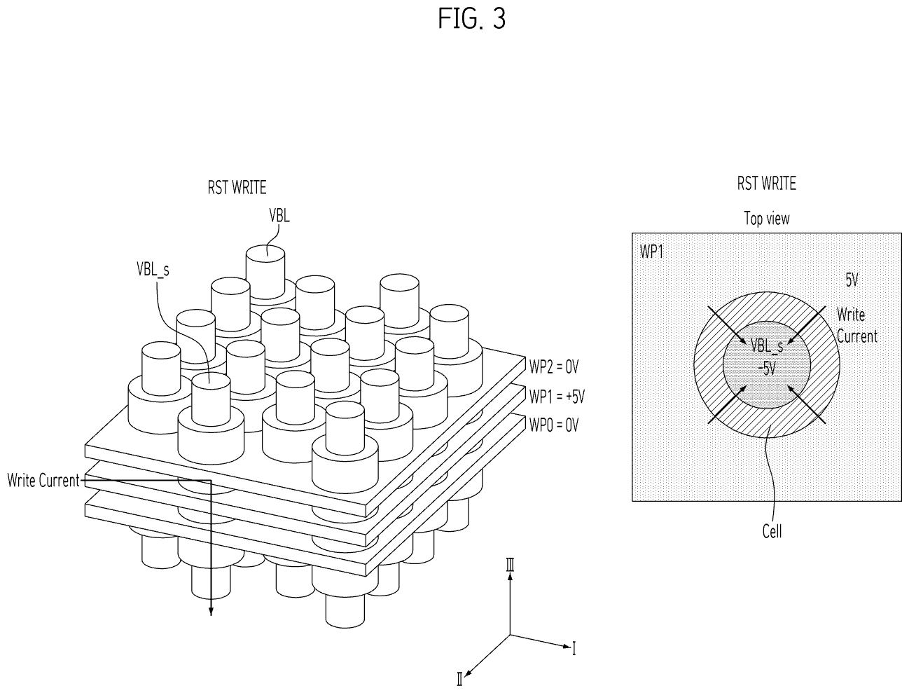

FIGS. 2 and 3 are diagrams that illustrate write operations of a memory cell array according to embodiments of the present disclosure.

FIG. 2 is a diagram that illustrates an operation of changing the state of a selected memory cell, among a plurality of memory cells included in a memory cell array according to an embodiment of the present disclosure, into a first state SET. In this case, the state of the memory cell may be changed into the first state SET or a second state RST in FIG. 3 through a write operation. A memory cell being in the first state SET may have a lower threshold voltage than a memory cell being in the second state RST. The first state SET may be a SET state, and the second state RST may be a RESET state. Accordingly, a write operation that changes the state of the memory cell into the first state SET, that is, the SET state, may be called a set write operation (SET WRITE). Furthermore, an operation of changing the state of a memory cell into the second state RST, that is, the RESET state, may be called a reset write operation (RST WRITE).

Referring to FIG. 2, a set write operation (SET WRITE) of the memory cell array according to an embodiment of the present disclosure may be performed as at least one word plane WP1, among a plurality of word planes WP0, WP1, and WP2, is selected and at least one vertical bit line VBL_s, among a plurality of vertical bit lines VBL, is selected. In this case, a first voltage may be applied to the selected word plane WP1, and a second voltage may be applied to the selected vertical bit line VBL_s. In this case, the second voltage may have a higher level than the first voltage. The first voltage may be a negative voltage, and the second voltage may be a positive voltage. In an embodiment, the first voltage may be −5 V, and the second voltage may be 5 V.

Accordingly, a write current (Write Current) that flows after performing a set write operation may be a current that flows from the selected bit line VBL_s to the selected word plane WP1. In this case, from the top view of the plane of the selected word plane WP1 in FIG. 2, it may be seen that the write current flows from the selected bit line VBL_s to the selected word plane WP1 through the memory cell.

The threshold voltage of a memory cell after a set write operation may have a lower level than the threshold voltage of the memory cell after a reset write operation.

Therefore, the threshold voltage of a memory material that is formed between the selected word plane WP1 and the selected bit line VBL_s, that is, the threshold voltage of a memory cell, may be changed depending on the direction of current.

FIG. 3 is a diagram that illustrates an operation of changing the state of a selected memory cell, among a plurality of memory cells included in a memory cell array according to an embodiment of the present disclosure, into the second state RST.

Referring to FIG. 3, a reset write operation (RST WRITE) of the memory cell array according to an embodiment of the present disclosure may be performed by selecting at least one word plane WP1 from among a plurality of word planes WP0, WP1, and WP2, and selecting at least one vertical bit line VBL_s from among a plurality of vertical bit lines VBL. In this case, a first voltage may be applied to the selected vertical bit line VBL, and a second voltage may be applied to the selected word plane WP1. The first voltage may have a lower level than the second voltage. The first voltage may be a negative voltage, and the second voltage may be a positive voltage. In an embodiment, the first voltage may be −5 V, and the second voltage may be 5 V.

Accordingly, a write current (Write Current) that flows after a reset write operation (RST WRITE) may be a current that flows from the selected word plane WP1 to the selected vertical bit line VBL_s. In this case, from the top view of the plane of the selected word plane WP1 in FIG. 3, it may be seen that the write current flows from the selected word plane WP1 to the selected vertical bit line VBL_s through a memory cell.

The threshold voltage of a memory cell after a reset write operation may have a higher level than the threshold voltage of the memory cell after a set write operation.

Therefore, the threshold voltage of a memory material that is formed between the selected word plane WP1 and the selected bit line VBL_s, that is, the threshold voltage of a memory cell, may be changed depending on the direction of current that flows through the memory cell.

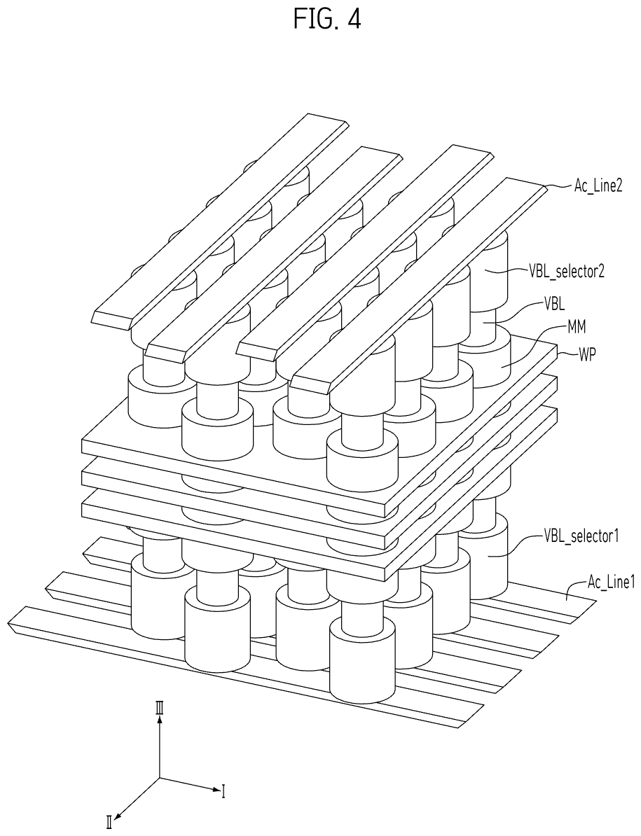

FIGS. 4 to 6 are diagrams that illustrate a memory cell array including a selection circuit according to embodiments of the present disclosure.

Referring to FIG. 4, a memory cell array including a selection circuit VBL_selector may include a first access line Ac_Line1, a first selection circuit VBL_selector1, a vertical bit line VBL, a word plane WP, a memory material MM, a second selection circuit VBL_selector2, and a second access line Ac_Line2.

The memory cell array may include at least one first access line Ac_Line1. For example, the memory cell array may include a plurality of first access lines Ac_Line1.

The plurality of first access lines Ac_Line1 may be formed on a plane that is defined in a first direction I and a second direction II. The plurality of first access lines Ac_Line1 may be formed to extend in the first direction I. The plurality of first access lines Ac_Line1 may each include a conductive material.

The memory cell array may include at least one first selection circuit VBL_selector1. For example, the memory cell array may include a plurality of first selection circuits VBL_selector1.

The plurality of first selection circuits VBL_selector1 may be respectively formed on the plurality of first access lines Ac_Line1. The plurality of first selection circuits VBL_selector1 may be electrically coupled to the plurality of first access lines Ac_Line1, and may be formed to extend in a third direction III. The plurality of first selection circuits VBL_selector1 may each include a selector material or the memory material MM capable of simultaneously performing memory and selector functions. The first selection circuits VBL_selector1 may include a chalcogenide-based material. The level of the threshold voltage of the first selection circuits VBL_selector1 may be changed depending on the direction of a current that flows through the first selection circuits VBL_selector1.

The memory cell array may include at least one vertical bit line VBL. For example, the memory cell array may include a plurality of vertical bit lines VBL.

The plurality of vertical bit lines VBL may be formed over the plurality of first selection circuits VBL_selector1. The plurality of vertical bit lines VBL may be electrically coupled to the plurality of first selection circuits VBL_selector1, and may be formed to extend in the third direction III. The plurality of vertical bit lines VBL may each include a conductive material.

The memory cell array may include portions of memory material MM that respectively wrap around or surround each of the plurality of vertical bit lines VBL. For example, a portion of memory material MM may be formed to surround at least a side, or to wrap around, a longitudinal axis of each of the plurality of vertical bit lines VBL that extends in the third direction III.

The memory cell array may include at least one word plane WP. For example, the memory cell array may include a plurality of word planes WP.

The plurality of word planes WP may be configured so that the plurality of word planes WP formed to extend in the first direction I and the second direction II are stacked in the third direction III. The word planes WP may include a conductive material. The plurality of vertical bit lines VBL and the plurality of memory materials MM may be formed to penetrate the plurality of word planes WP that are stacked. Embodiments comprise at least one word plane WP that extends in the first direction I and the second direction II on the plane that is defined in the first direction I and the second direction II. While FIG. 4 illustrates an embodiment with three word planes WP, the number and arrangement of word planes WP may vary between different embodiments. For example, a memory cell array according to another embodiment may include a plurality of word planes that are formed on the same plane that is defined in the first direction I and the second direction II. Furthermore, a plurality of word planes that are planar in the first direction I and the second direction II may be stacked in the third direction III and included in a memory cell array.

The memory cell array may include at least one second selection circuit VBL_selector2. For example, the memory cell array may include a plurality of second selection circuits VBL_selector2.

The plurality of second selection circuits VBL_selector2 may be formed over the plurality of vertical bit lines VBL. The plurality of second selection circuits VBL_selector2 may be electrically coupled to the plurality of vertical bit lines VBL, respectively, and may be formed to extend in the third direction III. The plurality of second selection circuits VBL_selector2 may include a selector material or a memory material MM capable of simultaneously performing memory and selector functions. The second selection circuits VBL_selector2 may include a chalcogenide-based material. The level of the threshold voltage of the second selection circuits VBL_selector2 may be changed depending on the direction of a current that penetrates the second selection circuits VBL_selector2.

The memory cell array may include at least one second access line Ac_Line2. For example, the memory cell array may include a plurality of second access lines Ac_Line2.

The plurality of second access lines Ac_Line2 may be formed on a plane that is defined in the first direction I and the second direction II. The plurality of second access lines Ac_Line1 may be formed to extend in the second direction II over the plurality of second selection circuits VBL_selector2, and may contact the plurality of second selection circuits VBL_selector2. The plurality of second access lines Ac_Line2 may each include a conductive material. In this case, the plurality of first access lines Ac_Line1 and the plurality of second access lines Ac_Line2 included in the memory cell array according to an embodiment of the present disclosure have been described as extending in different directions, but may be formed to extend in the same direction in another embodiment.

The memory material MM that surrounds each of the plurality of vertical bit lines VBL may be the same material or a different material from the memory material MM that is included in the first and second selection circuits VBL_selector1 and VBL_selector2. The memory material MM may include a chalcogenide-based material. The level of the threshold voltage of the memory material MM may be changed depending on the direction of a current that passed through the memory material MM. Furthermore, even if each of a material included in the first and second selection circuits VBL_selector1 and VBL_selector2 and a material that surrounds each of the plurality of vertical bit lines VBL are chalcogenide-based materials, the threshold voltage of each chalcogenide-based material may be different.

The first access line Ac_Line1 may be a word line, and the second access line Ac_Line2 may be a bit line, or vice versa. Accordingly, if the first access line Ac_Line1 is a bit line, the second access line Ac_Line2 may be a word line. In the following disclosure, when the first access line Ac_Line1 or the second access line Ac_Line2 is a bit line, such a bit line may be referred to as a horizontal bit line to distinguish that structure from the vertical bit line VBL. Reference to the first and second access lines as bit lines and word lines is for the purpose of describing exemplary embodiments, and the role of the access lines as bit lines or word lines may be reversed in other embodiments.

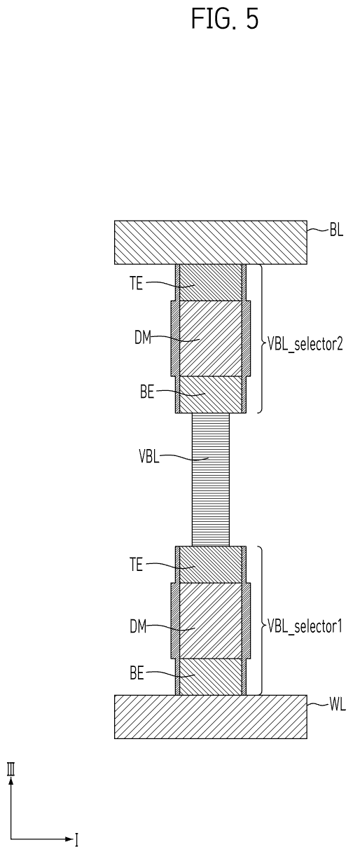

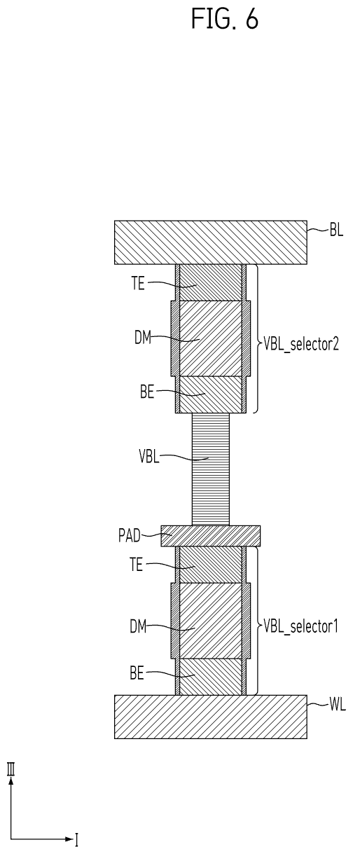

FIGS. 5 and 6 illustrate embodiments of the selection circuit illustrated in FIG. 4. FIGS. 5 and 6 are cross-sectional views of selection circuits illustrated along a cross-sectional plane that is defined in a first direction I and a third direction III, and each illustrate an embodiment of the first and second selection circuits VBL_selector1 and VBL_selector2 that are electrically coupled to both ends of one vertical bit line VBL. Furthermore, while FIGS. 5 and 6 each show embodiments in which the first access line Ac_Line1 is a word line WL and the second access line Ac_Line2 is a horizontal bit line BL, in other embodiments, the first access line Ac_Line1 may be a horizontal bit line BL and the second access line Ac_Line2 may be a word line.

Referring to FIG. 5, the first selection circuit VBL_selector1 may be formed over the word line WL. The vertical bit line VBL may be formed over the first selection circuit VBL_selector1. The second selection circuit VBL_selector2 may be formed over the vertical bit line VBL. A horizontal bit line BL may be formed over the second selection circuit VBL_selector2.

In this case, each of the first selection circuit VBL_selector1 and the second selection circuit VBL_selector2 may include a first (bottom) electrode BE, a switching material DM, and a second (top) electrode TE.

The first selection circuit VBL_selector1 may include the first electrode BE formed over the word line WL, the switching material DM formed over the first electrode BE, and the second electrode TE formed over the switching material DM. In this case, the vertical bit line VBL may be formed over the second electrode TE of the first selection circuit VBL_selector1.

The second selection circuit VBL_selector2 may include the first electrode BE formed over the vertical bit line VBL, the switching material DM formed over the first electrode BE, and the second electrode TE formed over the switching material DM. In this case, the horizontal bit line BL may be formed over the second electrode TE of the second selection circuit VBL_selector2.

In this case, the switching material DM included in each of the first and second selection circuits VBL_selector1 and VBL_selector2 may include a material with a threshold voltage which changes depending on the direction of a current that is passed through the material. For example, the switching material DM may include a memory material MM.

Referring to FIG. 6, a pad PAD may be additionally formed between the second electrode TE of the first selection circuit VBL_selector1 and the vertical bit line VBL. The pad PAD may include a conductive material. In an embodiment, the pad PAD may include tungsten (W). The pad PAD may be formed to reduce damage from processing that would otherwise occur to the first selection circuit VBL_selector1 when the vertical bit line VBL is formed over the first selection circuit VBL_selector1.

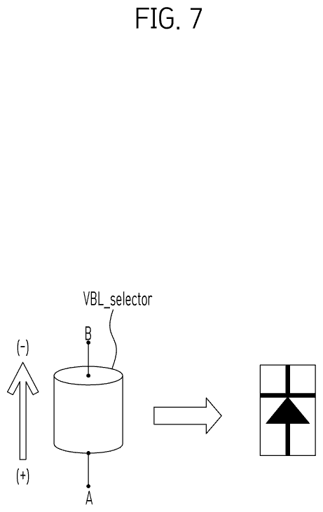

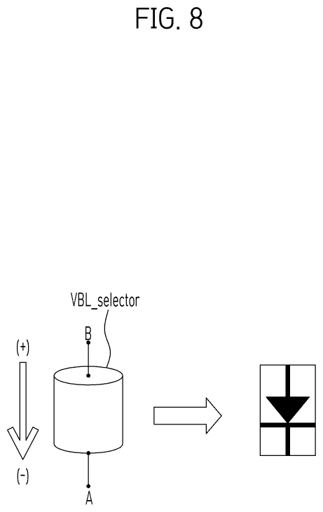

FIGS. 7 and 8 are diagrams that illustrate operations of a selection circuit according to embodiments of the present disclosure. In this case, the selection circuit VBL_selector illustrated in FIGS. 7 and 8 may be a circuit corresponding to each of the first and second selection circuits VBL_selector1 and VBL_selector2 illustrated in FIGS. 5 and 6. Furthermore, FIGS. 7 and 8 may each illustrate an embodiment of an operation of turning on the selection circuit VBL_selector by providing first and second terminals A and B with a first voltage and a second voltage, respectively, which have a sufficient difference between their levels to turn on or activate switching material DM.

Referring to FIG. 7, the first voltage may be applied to the first terminal A of the selection circuit VBL_selector. The second voltage may be applied to the second terminal B of the selection circuit VBL_selector. In this case, the first and second terminals A and B may correspond to the first and second electrodes BE and TE, respectively.

A difference between the levels of the first voltage and the second voltage may be a voltage level at which the switching material DM included in the selection circuit VBL_selector is turned on. Furthermore, the first voltage may have a higher voltage level than the second voltage. In an embodiment, the first voltage, that is, a positive voltage (+), may be provided to the first terminal A of the selection circuit VBL_selector and the second voltage, that is, a negative voltage (−), may be provided to the second terminal B of the selection circuit VBL_selector, thus turning on the selection circuit VBL_selector. A difference between the levels of the positive voltage (+) and the negative voltage (−) may be a voltage level sufficient to turn on the switching material DM.

When the selection circuit VBL_selector is turned on, a current may flow from the first terminal A to the second terminal B.

Thereafter, in a section in which a difference between the levels of the first and second terminals A and B is less than a level sufficient to turn on the switching material DM, a current may flow in the same direction as the direction of the current when the selection circuit VBL_selector is turned on. In a section in which a difference between the levels of the first and second terminals A and B is less than the level sufficient to turn on the switching material DM, the selection circuit VBL_selector may prevent a current from flowing in a direction different from the direction of the current when the selection circuit VBL_selector is turned on.

In other words, when the selection circuit VBL_selector is turned on so that a current flows from the first terminal A to the second terminal B through the selection circuit VBL_selector, the selection circuit VBL_selector may flow a current from the first terminal A to the second terminal B, and may prevent a current from flowing from the second terminal B to the first terminal A.

Referring to FIG. 8, the second voltage may be applied to the first terminal A of the selection circuit VBL_selector, and the first voltage may be applied to the second terminal B of the selection circuit VBL_selector. In this case, a difference between the levels of the first voltage and the second voltage may be a voltage level sufficient to turn on the switching material DM included in the selection circuit VBL_selector. Furthermore, the first voltage may have a higher voltage level than the second voltage. In an embodiment, the second voltage, that is, a negative voltage (−), may be provided to the first terminal A of the selection circuit VBL_selector and the first voltage, that is, a positive voltage (+), may be provided to the second terminal B of the selection circuit VBL_selector, thus turning on the selection circuit VBL_selector.

When the selection circuit VBL_selector is turned on, a current may flow from the second terminal B to the first terminal A.

The selection circuit VBL_selector that is turned on as described above may flow a current in the same direction as the direction of a current when the selection circuit VBL_selector is turned on in a section in which a difference between the levels of the first and second terminals A and B is less than a level sufficient to turn on the switching material DM. The selection circuit VBL_selector that has been turned on may prevent a current from flowing in a direction different from the direction of the current when the selection circuit VBL_selector is turned on in the section in which a difference between the levels of the first and second terminals A and B is less than the level sufficient to turn on the switching material DM.

In other words, when the selection circuit VBL_selector is turned on so that a current flows from the second terminal B to the first terminal A through the selection circuit VBL_selector, the selection circuit VBL_selector may flow the current from the second terminal B to the first terminal A, and may prevent a current from flowing from the first terminal A to the second terminal B.

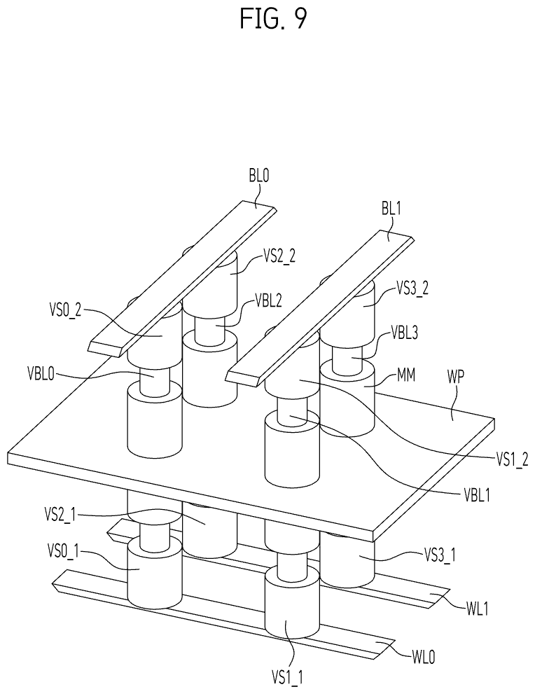

FIGS. 9 to 11 illustrate operations of selecting a vertical bit line of the memory cell array according to embodiments of the present disclosure.

FIG. 9 illustrates an operation of selecting one of a plurality of vertical bit lines VBL included in a memory cell array according to an embodiment of the present disclosure. In this case, for convenience of description, FIG. 9 illustrates a memory cell array with four vertical bit lines VBL0, VBL1, VBL2, and VBL3 that are electrically coupled between two word lines WL0 and WL1 and two horizontal bit lines BL0 and BL1 and any one of a plurality of word planes. However, the number of word lines, the number of horizontal bit lines, the number of vertical bit lines, and the number of word planes are not specifically limited, and may vary between different embodiments.

While the number of components of the memory cell array illustrated in FIG. 9 is different from that of the memory cell array illustrated in FIG. 4, the memory cell array illustrated in FIG. 9 and the memory cell array illustrated in FIG. 4 may have the same connections and arrangement between the components. Accordingly, the components of the memory cell array illustrated in FIG. 9 are described in brief.

Referring to FIG. 9, the memory cell array may include the first and second word lines WL0 and WL1, the first and second horizontal bit lines BL0 and BL1, a word plane WP_s, the first to fourth vertical bit lines VBL0, VBL1, VBL2, and VBL3, a memory material MM that wraps around or surrounds at least a side of each of the first to fourth vertical bit lines VBL0, VBL1, VBL2, and VBL3, and first to eighth selection circuits VS0_1, VS0_2, VS1_1, VS1_2, VS2_1, VS2_2, VS3_1, and VS3_2.

Each of the first to fourth vertical bit lines VBL0, VBL1, VBL2, and VBL3 each having sides surrounded by the memory material MM may be formed to penetrate the word plane WP_s.

The first selection circuit VS0_1, the third selection circuit VS1_1, the fifth selection circuit VS2_1, and the seventh selection circuit VS3_1 may be formed between the first to fourth vertical bit lines VBL0, VBL1, VBL2, and VBL3, respectively, and the first and second word lines WL0 and WL1.

The second selection circuit VS0_2, the fourth selection circuit VS1_2, the sixth selection circuit VS2_2, and the eighth selection circuit V3_2 may be formed between the first to fourth vertical bit lines VBL0, VBL1, VBL2, and VBL3, respectively, and the first and second horizontal bit lines BL0 and BL1.

The first vertical bit line VBL0 may be disposed between the first word line WL0 and the first horizontal bit line BL0. The first selection circuit VS0_1 may be disposed between the first vertical bit line VBL0 and the first word line WL0. The second selection circuit VS0_2 may be disposed between the first vertical bit line VBL0 and the first horizontal bit line BL0.

The second vertical bit line VBL1 may be disposed between the first word line WL0 and the second horizontal bit line BL1. The third selection circuit VS1_1 may be disposed between the second vertical bit line VBL1 and the first word line WL0. The fourth selection circuit VS1_2 may be disposed between the second vertical bit line VBL1 and the second horizontal bit line BL1.

The third vertical bit line VBL2 may be disposed between the second word line WL1 and the first horizontal bit line BL0. The fifth selection circuit VS2_1 may be disposed between the third vertical bit line VBL2 and the second word line WL1. The sixth selection circuit VS2_2 may be disposed between the third vertical bit line VBL2 and the first horizontal bit line BL0.

The fourth vertical bit line VBL3 may be disposed between the second word line WL1 and the second horizontal bit line BL2. The seventh selection circuit VS3_1 may be disposed between the fourth vertical bit line VBL3 and the second word line WL1. The eighth selection circuit VS3_2 may be disposed between the fourth vertical bit line VBL3 and the second horizontal bit line BL1.

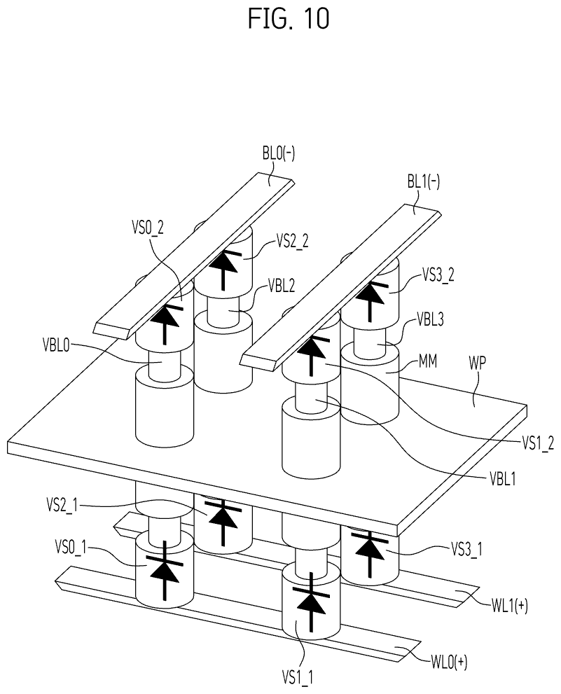

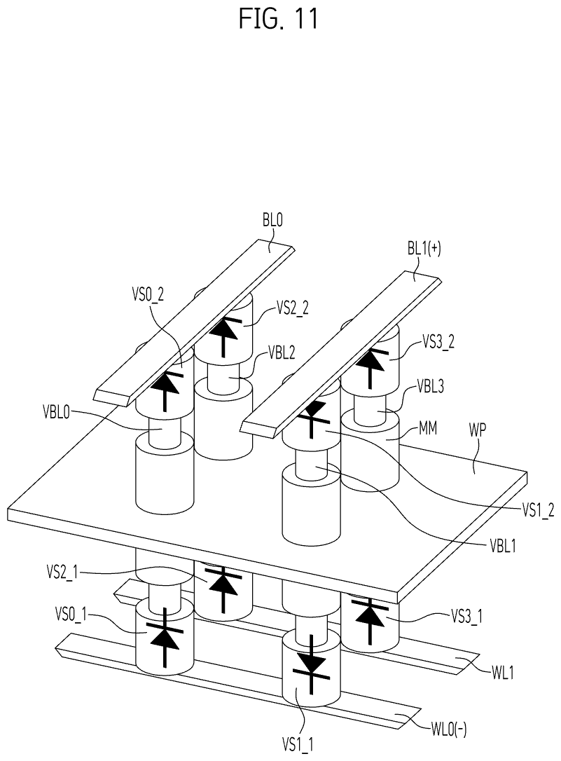

Operations of the memory cell array described above with respect to FIG. 9 according to an embodiment of the present disclosure are described as follows with reference to FIGS. 10 and 11.

Referring to FIG. 10, a first voltage may be provided to the first and second word lines WL0 and WL1. A second voltage may be provided to the first and second horizontal bit lines BL0 and BL1. The first voltage may have a higher level than the second voltage. For example, the first voltage may be a positive voltage (+), and the second voltage may be a negative voltage (−). In this case, a difference between the levels of the first voltage (+) and the second voltage (−) may be a high voltage level to the extent that the switching material DM of each of the first to eighth selection circuits VS0_1, VS0_2, VS1_1, VS1_2, VS2_1, VS2_2, VS3_1, and VS3_2 is turned on. The word plane WP may be in a floating state.

Accordingly, the first to eighth selection circuits VS0_1, VS0_2, VS1_1, VS1_2, VS2_1, VS2_2, VS3_1, and VS3_2 may be turned on. The first to eighth selection circuits VS0_1, VS0_2, VS1_1, VS1_2, VS2_1, VS2_2, VS3_1, and VS3_2 that have been turned on may flow a current from the first and second word lines WL0 and WL1 to the first and second horizontal bit lines BL0 and BL1.

After the operation of FIG. 10 is performed, an operation of FIG. 11 may be performed. In this case, it is to be noted that FIG. 11 merely illustrates an operation of the second vertical bit line VBL1, among the first to fourth vertical bit lines VBL0, VBL1, VBL2, and VBL3, being selected in an embodiment of an operation of selecting one of the plurality of vertical bit lines, and the present disclosure is not limited thereto.

Referring to FIG. 11, the second voltage (−) may be applied to the first word line WL0. The first voltage (+) may be applied to the second horizontal bit line BL1. In this case, a difference between the levels of the first voltage (+) and the second voltage (−) may be a high voltage level to the extent that the switching material DM included in each of the third and fourth selection circuits VS1_1 and VS1_2 is turned on. The word plane WP may be in the floating state.

Accordingly, the third and fourth selection circuits VS1_1 and VS1_2 may be turned on. The third and fourth selection circuits VS1_1 and VS1_2 that have been turned on may flow a current from the second horizontal bit line BL1 to the first word line WL0.

That is, only the third and fourth selection circuits VS1_1 and VS1_2, among the first to eighth selection circuits VS0_1, VS0_2, VS1_1, VS1_2, VS2_1, VS2_2, VS3_1, and VS3_2, may flow a current from the second horizontal bit line BL1 to the first word line WL0.

As a result, only the second vertical bit line VBL1, among the first to fourth vertical bit lines VBL0, VBL1, VBL2, and VBL3, may be selected so that a current may flow from the second horizontal bit line BL1 to the first word line WL0.

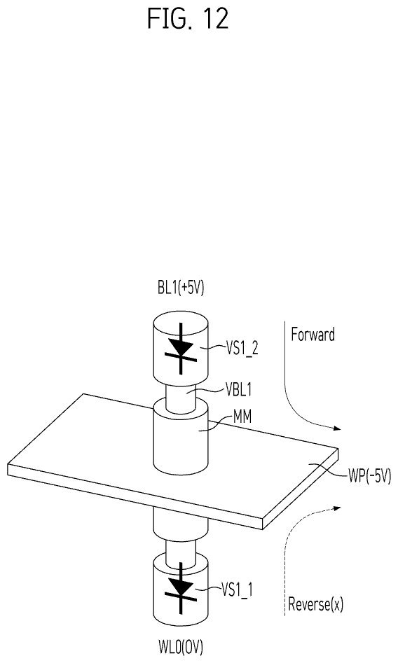

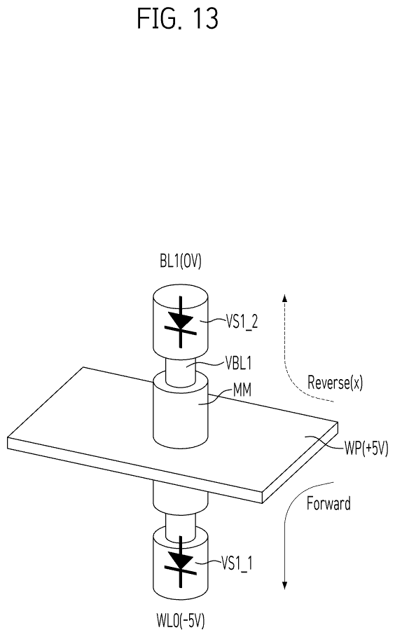

FIGS. 12 and 13 illustrate write operations of a memory cell array according to embodiments of the present disclosure. In particular, FIGS. 12 and 13 each illustrate write operations for a selected second vertical bit line VBL1, among the first to fourth vertical bit lines VBL0, VBL1, VLB2, and VBL3.

Referring to FIG. 12, after the second vertical bit line VBL1 is selected, a first voltage may be applied to the second horizontal bit line BL1, a ground voltage 0 V may be applied to the first word line WL0, and a second voltage may be applied to the word plane WP. In this case, the first voltage may have a higher level than the second voltage. The first voltage may have a higher level than the ground voltage. The second voltage may have a lower level than the ground voltage. The first voltage may be a positive voltage. The second voltage may be a negative voltage. In an embodiment, the first voltage may be +5 V, and the second voltage may be −5 V.

The first voltage +5 V may be transmitted to the fourth selection circuit VS1_2 through the second horizontal bit line BL1. The ground voltage 0 V may be transmitted to the third selection circuit VS1_1 through the first word line WL0.

Therefore, a current may flow in a forward direction of the fourth selection circuit VS1_2, that is, from the second horizontal bit line BL1 to the word plane WP through the fourth selection circuit VS1_2, the second vertical bit line VBL1, and the memory material MM. A current may not flow through the third selection circuit VS1_1 because the first and second voltages are provided in a reverse direction of the third selection circuit VS1_1.

As a result, a current may flow from the second vertical bit line VBL1 to the word plane WP through the memory material MM, and a write operation may be performed. As illustrated in FIG. 12, the memory material MM between the second vertical bit line VBL1 and the word plane WP, that is, a memory cell, may be written in the set state. Such an operation may be named set write (SET write).

Referring to FIG. 13, after the second vertical bit line VBL1 is selected, a ground voltage 0 V may be applied to the second horizontal bit line BL1, a second voltage may be applied to the first word line WL0, and a first voltage may be applied to the word plane WP. In this case, the first voltage may have a higher level than the second voltage. The first voltage may have a higher level than the ground voltage. The second voltage may have a lower level than the ground voltage. The first voltage may be a positive voltage. The second voltage may be a negative voltage. In an embodiment, the first voltage may be +5 V, and the second voltage may be −5 V.

The ground voltage 0 V may be transmitted to the fourth selection circuit VS1_2 through the second horizontal bit line BL1. The second voltage −5 V may be transmitted to the third selection circuit VS1_1 through the first word line WL0.

Therefore, a current may flow in a forward direction of the third selection circuit VS1_1, that is, from the word plane WP to the first word line WL0 through the memory material MM, the second vertical bit line VBL1, and the third selection circuit VS1_1. A current may not flow through the fourth selection circuit VS1_2 because the first and second voltages are provided in a reverse direction of the fourth selection circuit VS1_2.

As a result, a current may flow from the word plane WP to the first word line WL0 through the memory material MM, and a write operation may be performed. As illustrated in FIG. 13, the memory material MM between the second vertical bit line VBL1 and the word plane WP, that is, a memory cell, may be written in the reset state. Such an operation may be named reset write (RST write).

Furthermore, the memory cell array constructed as described above may read the memory cell in the same current direction as the direction used for the set write operation. When the memory cell is in the set state, the threshold voltage of the memory cell may be determined to be low because a current may flow through the memory cell in the same current direction as the direction used for the set write. When the memory cell is in the reset state, a current cannot flow through the memory cell because the first and second voltages are provided so that the current flows in a direction opposite to a direction used for the set write. In such a case, the threshold voltage of the memory cell may be determined to be high. Accordingly, the threshold voltage of a memory cell being in the set state may be determined to be lower than the threshold voltage of a memory cell being in the reset state.

Furthermore, a difference between the levels of voltages that are provided to a word line and a horizontal bit line in an operation of selecting a vertical bit line of a memory cell array according to an embodiment of the present disclosure may be greater than or equal to a difference between the levels of voltages that are provided to a word line and a horizontal bit line in a write operation.

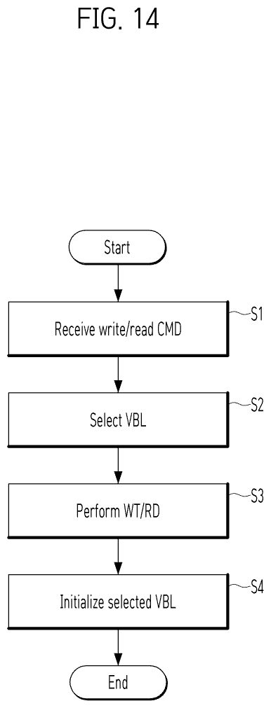

FIG. 14 is a flowchart that illustrates an operation of a memory device including a memory cell array according to an embodiment of the present disclosure.

Referring to FIG. 14, an operating method of the memory device including a memory cell array according to an embodiment of the present disclosure may include a command (Read/Write CMD) reception operation S1, a vertical bit line (VBL) selection operation S2, a command operation execution (WT/RD) operation S3, and a selected vertical bit line (VBL) initialization operation S4.

The command reception operation S1 may include an operation of receiving a write/read command CMD from an external device.

The vertical bit line selection operation S2 may include an operation of setting selection circuits connected to a selected vertical bit line in a state in which a word plane has been floated so that a current flows in a direction opposite to a direction in which a current flows into selection circuits connected to other vertical bit lines. For example, when the second vertical bit line VBL1, among the first to fourth vertical bit lines VBL0, VBL1, VBL2, and VBL3, is selected, the third and fourth selection circuits VS1_1 and VS1_2 connected to the second vertical bit line VBL1 may be set so that a current flows in a first direction, and selection circuits connected to the remaining vertical bit lines VBL0, VBL2, and VBL3 may be set so that a current flows in a second direction. Referring to FIGS. 10 and 11, the first direction may be a direction in which a current flows from the horizontal bit line BL1 to the word line WL0. The second direction may be a direction in which a current flows from the word lines WL0 and WL1 to the horizontal bit lines BL0 and BL1. In this case, the vertical bit line selection operation S2 may be an operation of performing a setting operation so that a current can flow into only the second vertical bit line VBL1 in the first direction, after performing a setting operation so that a current can flow into the first to fourth vertical bit lines VBL0, VBL1, VLB2, and VBL3 in the second direction.

The command operation execution operation S3 may include an operation of performing an operation for the command that has been received in the command reception operation S1 through the selected vertical bit line. When a write command Write CMD is received, the command operation execution operation S3 may include an operation of changing the state of a memory cell into the set state or the reset state in a direction in which a write current flows as the write current flows into the selected vertical bit line. Furthermore, when a read command Read CMD is received, the command operation execution operation S3 may include an operation of determining the state of a memory cell by providing a current to the memory cell in the same direction as a direction used for a set write operation.

The selected vertical bit line initialization operation S4 may include an operation of initializing the selected vertical bit line that has been set so that a current flows in the first direction, so that a current flows in the second direction identically with other vertical bit lines. For example, the selected vertical bit line initialization operation S4 may include an operation of setting the selection circuits connected to the selected vertical bit line so that a current flows in the second direction, that is, from a word line to a horizontal bit line.

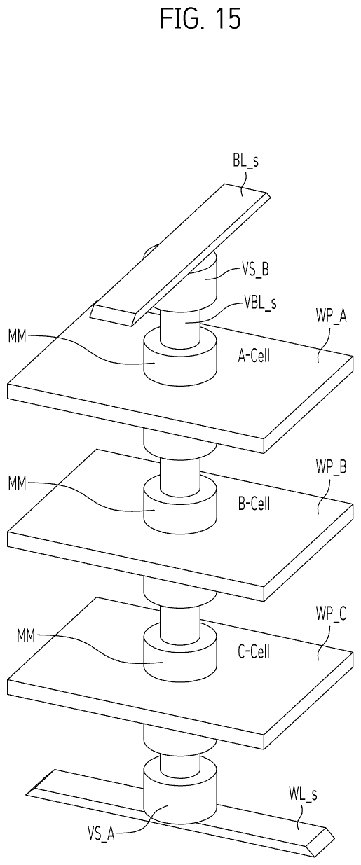

FIG. 15 is a diagram that illustrates an operation of a memory device including a memory cell array according to another embodiment of the present disclosure.

FIG. 15 illustrates a state in which one horizontal bit line BL_s, among a plurality of horizontal bit lines, has been selected, one word line WL_s, among a plurality of word lines, has been selected, and one vertical bit line VBL_s, among a plurality of vertical bit lines, has been selected. In this case, a memory material MM between a first word plane WP_A and the selected vertical bit line VBL_s may operate as a first memory cell A-Cell. A memory material MM between a second word plane WP_B and the selected vertical bit line VBL_s may operate as a second memory cell B-Cell.

A memory material MM between a third word plane WP_C and the selected vertical bit line VBL_s may operate as a third memory cell C-Cell.

An operation of selecting one vertical bit line, among a plurality of vertical bit lines, may be the same as the operation described with reference to FIG. 10 and thus is omitted for the sake of brevity.

After the vertical bit line VBL_s is selected, the plurality of memory cells A-Cell, B-Cell, and C-Cell that are formed between the selected vertical bit line VBL_s and the plurality of word planes WP_A, WP_B, and WP_C may be consecutively written or consecutively read.

An example of an operation of consecutively writing the first to third memory cells A-Cell, B-Cell, and C-Cell will now be described.

A set write operation for the first memory cell A-Cell may be an operation of applying a first voltage to the selected horizontal bit line BL_s, applying a ground voltage to a selected word line WL_s, and applying a second voltage to the first word plane WP_A. At this time, the second and third word planes WP_B and WP_C may be in the floating state. At this time, the first voltage may have a higher level than the ground voltage. The second voltage may have a lower level than the ground voltage.

A reset write operation for the first memory cell A-Cell may be an operation of applying the ground voltage to the selected horizontal bit line BL_s, applying the second voltage to the selected word line WL_s, and applying the first voltage to the first word plane WP_A. At this time, the second and third word planes WP_B and WP_C may be in the floating state.

A set write operation for the second memory cell B-Cell may be an operation of applying the first voltage to the selected horizontal bit line BL_s, applying the ground voltage to the selected word line WL_s, and applying the second voltage to the second word plane WP_B. At this time, the first and third word planes WP_A and WP_C may be in the floating state.

A reset write operation for the second memory cell B-Cell may be an operation of applying the ground voltage to the selected horizontal bit line BL_s, applying the second voltage to the selected word line WL_s, and applying the first voltage to the second word plane WP_B. At this time, the first and third word planes WP_A and WP_C may be in the floating state.

A set write operation for the third memory cell C-Cell may be an operation of applying the first voltage to the selected horizontal bit line BL_s, applying the ground voltage to the selected word line WL_s, and applying the second voltage to the third word plane WP_C. At this time, the first and second word planes WP_A and WP_B may be in the floating state.

A reset write operation for the third memory cell C-Cell may be an operation of applying the ground voltage to the selected horizontal bit line BL_s, applying the second voltage to the selected word line WL_s, and applying the first voltage to the third word plane WP_C. At this time, the first and second word planes WP_A and WP_B may be in the floating state.

As described above, after a vertical bit line is selected, consecutive write operations for a plurality of memory cells that are formed between the vertical bit line and a plurality of word planes may be divided into a set write operation and a reset write operation based on a voltage that is provided to each of a selected word line and a selected horizontal bit line. Furthermore, the consecutive write operations may be performed on the plurality of memory cells by providing one of the first and second voltages to the word plane of a memory cell on which a write operation is performed, among the plurality of memory cells, and floating the word planes of memory cells on which a write operation is not performed, among the plurality of memory cells.

Furthermore, after the vertical bit line is selected, in a read operation for the plurality of memory cells that is formed between the vertical bit line and the plurality of word planes, a voltage may be applied to the selected horizontal bit line and the selected word line so that a current can flow into a selected memory cell in the same direction as the set write operation. Thereafter, consecutive read operations may be performed on the plurality of memory cells by providing a voltage at a specific level to the word plane of a memory cell on which a read operation is performed, among the plurality of memory cells, and floating the word planes of memory cells on which a read operation is not performed.

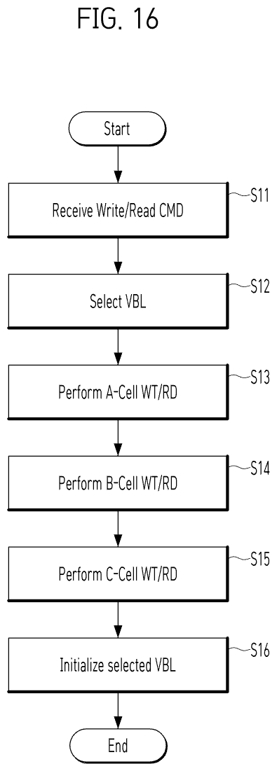

FIG. 16 is a flowchart that illustrates an operation of a memory device including a memory cell array according to another embodiment of the present disclosure.

Referring to FIG. 16, an operating method of the memory device including the memory cell array according to another embodiment of the present disclosure may include a command (Write/Read CMD) reception operation S11, a vertical bit line (VBL) selection operation S12, a consecutive command operation (A-Cell WT/RD, B-Cell WT/RD, and C-Cell WT/RD) execution operation S13, S14, and S15, and a selected vertical bit line (VBL) initialization operation S16.

The command reception operation S11 may include an operation of receiving a write/read command CMD from an external device.

The vertical bit line selection operation S12 may include an operation of setting selection circuits coupled to a selected vertical bit line in the state in which a plurality of word planes has been floated so that a current flows in a direction opposite to a direction in which a current flows into selection circuits connected to other vertical bit lines. For example, when the second vertical bit line VBL1, among the first to fourth vertical bit lines VBL0, VBL1, VBL2, and VBL3, is selected, the third and fourth selection circuits VS1_1 and VS1_2 connected to the second vertical bit line VBL1 may be set so that a current flows in a first direction, and selection circuits connected to the remaining vertical bit lines VBL0, VBL2, and VBL3 may be set so that a current flows in a second direction. Referring to FIGS. 10 and 11, the first direction may be a direction in which a current flows from the horizontal bit line BL1 to the word line WL0. The second direction may be a direction in which a current flows from the word lines WL0 and WL1 to the horizontal bit lines BL0 and BL1. In this case, the vertical bit line selection operation S2 may be an operation of performing a setting operation so that a current can flow into only the second vertical bit line VBL1 in the first direction, after performing a setting operation so that a current can flow into the first to fourth vertical bit lines VBL0, VBL1, VLB2, and VBL3 in the second direction.

The consecutive command operation execution operations S13, S14, and S15 may include an operation of consecutively performing operations on a plurality of memory cells that are formed over the selected vertical bit line based on the command that has been received in the command reception operation S1. When a write command Write CMD is received, the consecutive command operation execution operations S13, S14, and S15 may include an operation of consecutively changing the state of each of the plurality of memory cells into the set state or the reset state in a direction in which a write current flows by flowing the write current to each of the plurality of memory cells formed over the selected vertical bit line. The consecutive command operation execution operations S13, S14, and S15 may include a plural memory cell command operation execution operation of performing S13, S14, and S15. For example, the consecutive command operation execution operations S13, S14, and S15 may include a first memory cell command operation execution operation S13, a second memory cell command operation execution operation S14, and a third memory cell command operation execution operation S15. The first memory cell command operation execution operation S13 is an operation of writing the first memory cell A-Cell, and may include an operation of applying a first voltage or a second voltage to the first word plane WP_A so that a write current passes through the first memory cell A-Cell and an operation of floating the second and third word planes WP_B and WP_C. The second memory cell command operation execution operation S14 is an operation of writing the second memory cell B-Cell, and may include an operation of applying the first voltage or the second voltage to the second word plane WP_B so that a write current passes through the second memory cell B-Cell and an operation of floating the first and third word planes WP_B and WP_C. The third memory cell command operation execution operation S15 is an operation of writing the third memory cell C-Cell, and may include an operation of applying the first voltage or the second voltage to the third word plane WP_C so that a write current passes through the third memory cell C-Cell and an operation of floating the first and second word planes WP_A and WP_B.

Furthermore, when a read command Read CMD is received, the consecutive command operation execution operations S13, S14, and S15 may include an operation of consecutively determining the state of each of the plurality of memory cells by providing a current to each of the plurality of memory cells in the same direction as the direction used for a set write operation.

The first memory cell command operation execution operation S13 is an operation of reading the first memory cell A-Cell, and may include an operation of applying the second voltage to the first word plane WP_A so that a read current is provided to the first memory cell A-Cell and an operation of floating the second and third word planes WP_B and WP_C. The second memory cell command operation execution operation S14 is an operation of reading the second memory cell B-Cell, and may include an operation of applying the second voltage to the second word plane WP_B so that a read current is provided to the second memory cell B-Cell and an operation of floating the first and third word planes WP_B and WP_C. The third memory cell command operation execution operation S15 is an operation of reading the third memory cell C-Cell, and may include an operation of applying the second voltage to the third word plane WP_C so that a read current is provided to the third memory cell C-Cell and an operation of floating the first and second word planes WP_A and WP_B.

The selected vertical bit line initialization operation S16 may include an operation of initializing the selected vertical bit line that has been set so that a current flows in the first direction, so that a current flows in the second direction in the same manner as the other vertical bit lines. For example, the selected vertical bit line initialization operation S16 may include an operation of setting the selection circuits connected to the selected vertical bit line so that a current flows in the second direction, that is, from the word line to the horizontal bit line.

Although embodiments according to the technical spirit of the present disclosure have been described above with reference to the accompanying drawings, the embodiments have been provided to merely describe embodiments according to concepts of the present disclosure, and the scope of the present disclosure is not limited to the specific embodiments. A person having ordinary knowledge in the art to which the present disclosure pertains may substitute, modify, and change the embodiments in various ways without departing from the technical spirit of the present disclosure written in the claims. Such substitutions, modifications, and changes are within the scope of the present disclosure.

What is claimed is:

1. A memory device comprising:
a plurality of vertical bit lines disposed between a plurality of first access lines and a plurality of second access lines;
a plurality of first selection circuits disposed between the plurality of vertical bit lines and the plurality of first access lines; and
a plurality of second selection circuits disposed between the plurality of vertical bit lines and the plurality of second access lines.

2. The memory device of claim 1, further comprising a memory material that surrounds at least a side of each of the plurality of vertical bit lines.

3. The memory device of claim 2, wherein each selection circuit of the plurality of first selection circuits and the plurality of second selection circuits comprises a first electrode, a switching material, and a second electrode.

4. The memory device of claim 3, wherein the switching material includes the same material as the memory material.

5. The memory device of claim 3, wherein the switching material and the memory material each comprises a chalcogenide-based material.

6. The memory device of claim 5, wherein threshold voltages of the switching material and the memory material are different from each other.

7. The memory device of claim 1, further comprising a plurality of word planes,
wherein the plurality of vertical bit lines and the memory material penetrate the plurality of word planes.

8. The memory device of claim 3, wherein the plurality of first selection circuits and the plurality of second selection circuits are configured to be set so that a current flows in a first direction by applying a first voltage to each of the plurality of first access lines and applying a second voltage to each of the plurality of second access lines.

9. The memory device of claim 8, wherein a difference between levels of the first and second voltages is sufficient to turn on the switching material.

10. The memory device of claim 9, wherein the plurality of first selection circuits and the plurality of second selection circuits are set so that a current flows through a first vertical bit line of the plurality of vertical bit lines in a second direction by applying the second voltage to one of the plurality of first access lines, and applying the first voltage to one of the plurality of second access lines.

11. The memory device of claim 10, wherein the first direction and the second direction are different directions.

12. The memory device of claim 10, wherein a first selection circuit and a second selection circuit that are coupled to the first vertical bit line are set to flow a current in the second direction.

13. The memory device of claim 10, wherein the memory device is configured to perform a write operation or a read operation on one of a plurality of memory cells that is formed in the one vertical bit line.

14. The memory device of claim 10, wherein the memory device is configured to perform a write operation consecutively performed or a read operation consecutively on a plurality of memory cells that is formed in the one vertical bit line.

15. A memory device comprising:
a plurality of first selection circuits disposed over a plurality of first access lines;
a plurality of vertical bit lines disposed over the plurality of first selection circuits, respectively;
a plurality of memory cells each comprising a memory material that surrounds at least a side of each of the plurality of vertical bit lines;
a plurality of second selection circuits disposed over the plurality of vertical bit lines; and
a plurality of second access lines disposed over the plurality of second selection circuits,
wherein each of the plurality of first selection circuits and the plurality of second selection circuits are set so that a current flows in a first direction or a second direction.

16. The memory device of claim 15, wherein the current that flows in the first direction is a current that flows from the first access line to the second access line through the vertical bit line.

17. The memory device of claim 16, wherein the current that flows in the second direction is a current that flows from the second access line to the first access line through the vertical bit line.

18. The memory device of claim 15, wherein each of the first and second selection circuits comprises a first electrode, a switching material, and a second electrode.

19. The memory device of claim 18, wherein the switching material is with the same material as the memory material.

20. The memory device of claim 18, wherein the switching material and the memory material each comprise a chalcogenide-based material.

21. The memory device of claim 20, wherein threshold voltages of the switching material and the memory material are different from each other.

22. The memory device of claim 17, wherein the plurality of first selection circuits and the plurality of second selection circuits are set so that a current flows through a selected vertical bit line in a different direction from unselected vertical bit lines of the plurality of vertical bit lines.

23. The memory device of claim 22, wherein when the plurality of first selection circuits and the plurality of second selection circuits are set so that a current flows through the plurality of vertical bit lines in the second direction, one of the plurality of first selection circuits and one of the plurality of second selection circuits are set so that a current flows through the selected vertical bit line in the first direction.

24. A method for operating a memory device, comprising:
receiving a command;
selecting a vertical bit line from a plurality of vertical bit lines while a plurality of word planes are in a floating state;
performing an operation according to the command on at least one memory cell from a plurality of memory cells coupled to the selected vertical bit line; and
initializing the selected vertical bit line.

25. The method of claim 24, wherein selecting the vertical bit line comprises:
performing a first setting operation to enable a current to flow through the plurality of vertical bit lines in a first direction; and
performing a second setting operation to enable a current to flow through only the selected vertical bit line in a second direction.

26. The method of claim 25, wherein the first direction and the second direction are different directions.

27. The method of claim 25, wherein performing the operation according to the command comprises performing a write operation or a read operation according to the command on one of the plurality of memory cells coupled to the selected vertical bit line.

28. The method of claim 24, wherein performing the operation according to the command comprises:
applying a specific voltage to one of the plurality of word planes coupled to the selected vertical bit line, and
floating the remaining word planes.

29. The method of claim 25, wherein performing the operation according to the command comprises performing consecutive write or read operations according to the command on the plurality of memory cells that are coupled to the selected vertical bit line.

30. The method of claim 29, wherein performing the operation according to the command comprises consecutively repeating an operation of applying a specific voltage to one of the plurality of word planes and floating the remaining word planes.
